(19) United States
(12) Patent Application Publication
(10) Pub. No.: US 2026/0128394 A1
(43) Pub. Date: May 7, 2026

(54) PRINTED CIRCUIT BOARD COUPLING

(71) Applicant: Infineon Technologies AG, Neubiberg (DE)

(72) Inventors: Christian WALTHER, München (DE); Markus EKLER, Feldkirchen (DE); Philipp VOGEL, München (DE); Maximilian MÖNIKES, München (DE)

(21) Appl. No.: 19/321,528

(22) Filed: Sep. 8, 2025

(30) Foreign Application Priority Data
Nov. 5, 2024 (DE) 102024210631.3

(51) Int. Cl. H01M 10/42; B60R 16/033; H05K 1/14

(52) U.S. Cl. CPC H01M 10/425; B60R 16/033; H05K 1/14; H01M 2010/4271; H01M 2220/20; H05K 2201/10189

(57) ABSTRACT

A battery management system is disclosed. The battery management system comprises a plurality of printed circuit boards. A first printed circuit board (126) and a second printed circuit board are galvanically isolated from each other and arranged for transferring an electronic signal via a non-conductive electronic coupling between each other. Further, a method for arranging and operating the battery management system is disclosed.

### TECHNICAL FIELD

The present disclosure relates to a battery management system, a method for arranging and operating the battery management system and a use thereof. The disclosed battery management system and the disclosed method may specifically be used in an automotive application, such as for controlling battery cells in a vehicle. However, other applications may of course also be feasible.

### BACKGROUND

Battery management systems typically control several battery cells in at least partially different voltage domains. Thus, several cell supervision circuits, each controlling different battery cells, may be interconnected for forming the battery management system. Specifically, the cell supervision circuits may be arranged in a daisy chain. The cell supervision circuits may be galvanically isolated, such as a by using a capacitor for providing the galvanic isolation. In practice, the cell supervision circuits are typically daisy chained by using a two-wire communication bus, such that two plugs need to be placed during manufacturing. This typically involves a labor-intensive process, which specifically requires manual labor. Thus, there specifically is a need for reducing the effort for arranging the battery management system and more specifically for eliminating manual labor in this process.

### SUMMARY

In a first aspect, a battery management system is disclosed. The battery management system comprises a plurality of printed circuit boards. A first printed circuit board and a second printed circuit board are galvanically isolated from each other. The first printed circuit board and the second printed circuit board are further arranged for transferring an electronic signal via a non-conductive electronic coupling between each other.

In a further aspect, a method is disclosed. The method comprises:
a) arranging a first printed circuit board and a second printed circuit board within a battery management system such that the first printed circuit board and the second printed circuit board are galvanically isolated and electronically coupled via a non-conductive electronic coupling, and
b) transferring an electronic signal between the first printed circuit board and the second printed circuit board via the non-conductive electronic coupling between the first printed circuit board and the second printed circuit board.

In a further aspect, a use of the battery management system and/or the method for an automotive application is disclosed.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrates an example of an electronic setup of a battery management system.

FIG. 2 schematically illustrates an example of an arrangement of two printed circuit boards within the battery management system.

FIG. 3 schematically illustrates an example of an arrangement of three printed circuit boards within the battery management system.

FIG. 4 schematically illustrates an example of a mechanical setup of the battery management system.

IG. 5 illustrates a flow chart of an example of a method for arranging and operating the battery management system.

### DETAILED DESCRIPTION

The examples described herein provide considerable advantages. Specifically, the disclosed battery management system comprises a plurality of printed circuit boards which are arranged for transferring an electronic signal via a non-conductive electronic coupling, such as a capacitive coupling. Thus, the printed circuit boards, which may carry cell supervision circuits for monitoring the battery cells, may be arranged so that they form a capacitive coupling between each other, such as by at least partially overlapping with each other. Such an arrangement of the printed circuits boards can be automated during manufacturing. As a result, a manual placing of plugs for connecting the cell supervision circuits may not be required anymore, such that the manufacturing effort for arranging the battery management system can be significantly reduced.

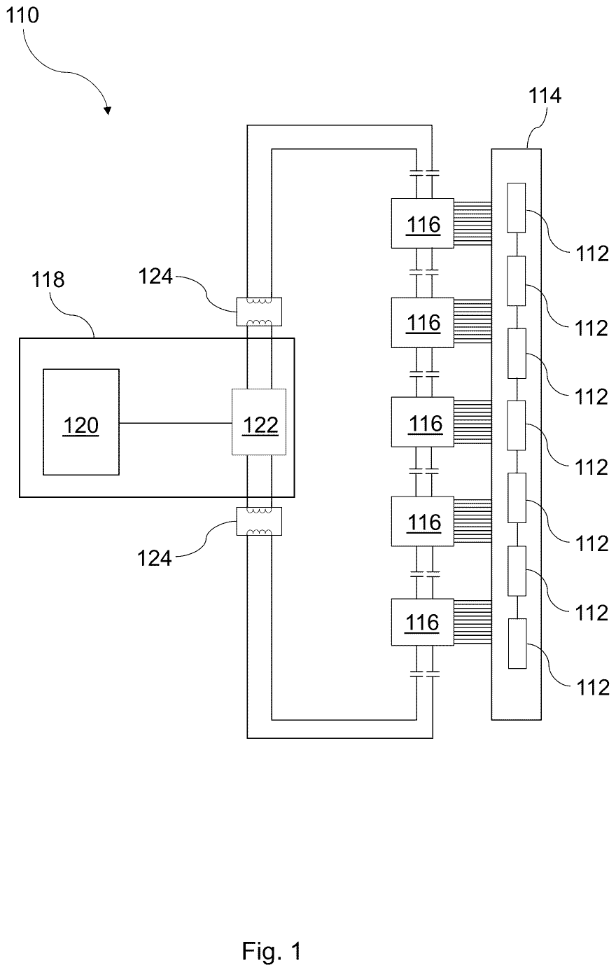

FIG. 1 schematically illustrates an example of an electronic setup of a battery management system 110. The battery management system 110 may be configured for controlling, monitoring or regulating one or more battery cells 112. Thus, the battery management system 110 may be configured for determining a physical property of at least one battery cell 112, such as a charging status, a temperature or an output voltage. The battery cells 112 or at least some of the battery cells 112 may form a battery stack 114, such as by connecting a plurality of battery cells 112. The battery management system 110 may comprise at least one cell supervision circuit 116. The cell supervision circuit 116 may be configured for monitoring at least one battery cell 112. Thus, the cell supervision circuit 116 may be configured for sensing at least one physical parameter of a battery cell 112. Additionally or alternatively, the cell supervision circuit 116 may be configured for regulating a battery cell 112, such as for disconnecting or connecting a battery cell 112.

The battery management system 110 may be a high voltage battery management system, specifically in a range from 120 V to 1500 V, more specifically in a range from 400 V to 800 V. Additionally or alternatively, the battery management system 110 may be a distributed battery management system. Thus, the battery management system 110 may comprise a plurality of cell supervision circuits 116. The cell supervision circuits 116 may be spatially distributed. The battery management system 110 may further comprise a host controller 118. The host controller 118 may be a main controller of the batter management system 110. Thus, the host controller 118 may be a superordinate controller, specifically a superordinate controller to the cell supervision circuits 116. The host controller 118 may be configured for controlling the battery management system 110, specifically for controlling the battery management system 110 overall or globally. Thus, the host controller 118 may for instance receive monitoring information from the cell supervision circuits 116, may evaluate the information and may transmit regulating information to the cell supervision circuits 116. The host controller 118 may comprise a microcontroller. The microcontroller 120 may be configured for evaluating or processing information. The host controller may further comprise a transceiver 122. The transceiver 122 may be configured for receiving and/or transmitting information.

The battery management system 110 and specifically the distributed battery management system 110 may be an interconnected battery management system 110. Thus, the components of the battery management system 110 may at least partially and/or indirectly be connected to each other. Specifically, the cell supervision circuits 116 may be arranged in a daisy chain topology. At least one cell supervision circuit 116 may be connected to the host controller 118 and specifically to the transceiver 122 of the host controller 118. As an example, two cell supervision circuits 116 may be connected to the host controller 118 and specifically to the transceiver 122 of the host controller 118, such as in a ring topology. Other topologies may however also be feasible. The cell supervision circuits 116 may be galvanically isolated, specifically from each other and/or from the host controller 118. Thus, the battery management system 110 may comprise at least one transformer 124. The transformer 124 may be configured for inductively coupling the host controller 118 to at least one cell supervision circuit 116. The transformer 124 may be arranged between the host controller 118 and a cell supervision circuit 116. In case of the above-indicated ring topology, the battery management system 110 may for instance comprise two transformers 124 between the host controller 118 and the daisy chained cell supervision circuits 116. In principle, besides the indicated inductive coupling, another electronic coupling to the host controller 118, such as a capacitive coupling, may also be feasible.

The cell supervision circuits 116 may for instance be capacitively coupled to each other. However, also here, another electronic coupling between the cell supervision circuits 116, such as an inductive coupling, may be feasible as well. As indicated, the electronic coupling between two neighboring cell supervision circuits 116 may be achieved by using a two-wired connection with plugs which may have to be placed manually during manufacturing. However, the

electronic coupling may also be archived in another more advantageous way as will be described in the following. Specifically, the presented kind of electronic coupling may significantly reduce the manufacturing effort for arranging the battery management system 110 and more specifically eliminate manual labor in the process.

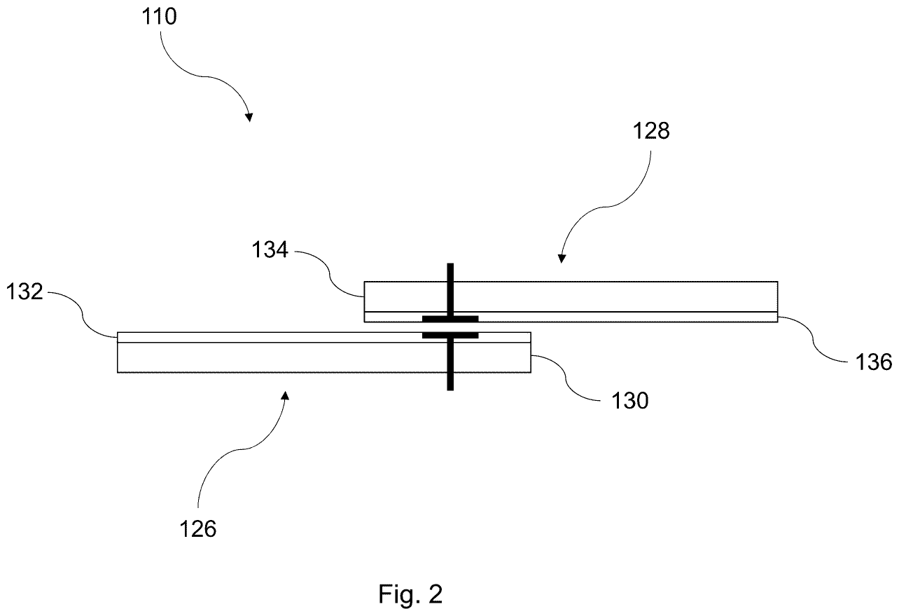

FIG. 2 schematically illustrates an example of an arrangement of two printed circuit boards 126 and 128 within the battery management system 110. Thus, the battery management system 110 comprises at least a first printed circuit board 126 and a second printed circuit 128. The printed circuit boards 126 and 128 may be configured for carrying one or more electronic circuits, such as a cell supervision circuit 116. The printed circuit boards 126 and 128 may comprise traces for connecting the electronic circuits. The printed circuit boards 126 and 128 may comprise a substrate for mechanically carrying the electronic circuits. At least one of the printed circuit boards 126 and 128 may be a flexible printed circuit board. In other words, at least one of the printed circuit boards 126 and 128 may be flexible or bendable, at least to a certain extent. Thus, the above-mentioned substrate may be a flexible substrate, specifically a flexible plastic substrate.

Specifically, the first printed circuit board 126 and the second printed circuit board 128 may each carry a cell supervision circuit 116. In other words, the cell supervision circuits 116 may be mounted on the printed circuit boards 126 and 128. Instead of manually placing plugs between the cell supervision circuits 116, the cell supervision circuits 116 may now also be connected in a galvanically isolated fashion by suitably arranging the first printed circuit board 126 and the second printed circuit board 128. Thus, the first printed circuit board 126 and the second printed circuit board 128 are galvanically isolated from each other. Further, the first printed circuit board 126 and the second printed circuit board 128 are arranged for transferring an electronic signal via a non-conductive electronic coupling between each other. Thus, the first printed circuit board 126 and the second printed circuit board 128 may be coupled indirectly, such as without direct conduction or resistive conduction between the first printed circuit board 126 and the second printed circuit board 128. The non-conductive electronic coupling may specifically be a capacitive coupling. Thus, an electronic signal, such as a voltage or a current, may be transferred between the printed circuit boards 126 and 128 via a change in an electric field formed between the printed circuit boards 126 and 128 through their arrangement. However, other electronic couplings such as specifically an inductive coupling may also be feasible. Thus, the non-conductive electronic coupling may for instance alternatively be or comprise an inductive coupling.

As anticipated by the capacitor symbol shown in FIG. 2, the first printed circuit board 126 and the second printed circuit 128, due to their arrangement, may form a capacitor and specifically a plate capacitor. Thus, the first printed circuit board 126 and the second printed circuit board 128 may at least partially overlap with each other. The first printed circuit board 126 may comprise a first conducting layer 130 and a first isolating layer 132. The second printed circuit board 128 may comprise a second conducting layer 134. The first printed circuit board 126 and the second printed circuit board 128 may at least partially be arranged such that the first conducting layer 130 and the second conducting layer 134 are spatially separated by the first isolating layer 132. Additionally, the second printed circuit board 128 may further comprise a second isolating layer 136. The first printed circuit board 126 and the second printed circuit board 128 may then at least partially be arranged such that the first conducting layer 130 and the second conducting layer 134 are spatially separated by the first isolating layer 132 and the second isolating layer 136. The first printed circuit board 126 and the second printed circuit board 128 may be spaced apart by a gap as shown in FIG. 2 for a better understanding. However, preferably, the first isolating layer 132 may be in direct contact with the second isolating layer 136.

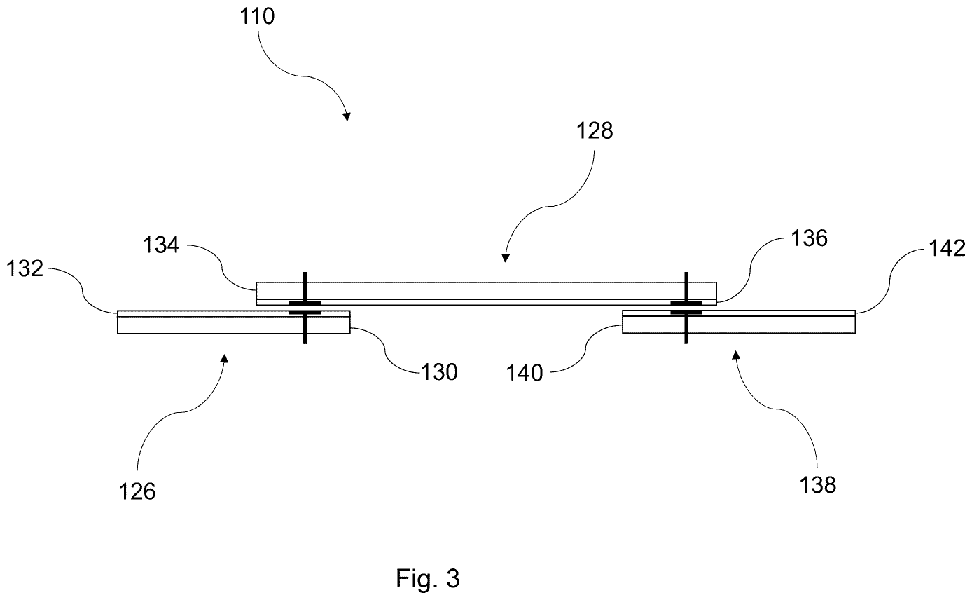

FIG. 3 schematically illustrates an example of an arrangement of three printed circuit boards 126, 128 and 138 within the battery management system 110. Thus, the battery management system 110 may specifically comprise a third printed circuit board 138. The third printed circuit board 138 may be of the same kind as the first printed circuit board 126 and the second printed circuit board 128. Thus, the third printed circuit board 138 may also specifically be a flexible printed circuit board. With respect to the description of the arrangement of the first printed circuit board 126 and the second printed circuit board 128 in FIG. 3, reference may also be made to the description of FIG. 2. As FIG. 3 shows, the second printed circuit board 128 and the third printed circuit board 138 may also at least partially overlap with each other and thus form a capacitor and specifically a plate capacitor. Thus, the second printed circuit board 128 and the third printed circuit 138 board may also be galvanically isolated from each other. Further, the second printed circuit board 128 and the third printed circuit 138 board may also be arranged for transferring electronic signals via a non-conductive electronic coupling and specifically via a capacitive coupling between each other. Overall, the first printed circuit board 126, the second printed circuit board 128 and the third printed circuit board 138 may be arranged for transferring an electronic signal between the first printed circuit board 126 and the third printed circuit board 138 via the second printed circuit board 128. Thus, in the arrangement shown in FIG. 3, the second printed circuit 128 may specifically be a connecting printed circuit board between first printed circuit board 126 and the third printed circuit board 138.

The third printed circuit board 138 may comprise a third conducting layer 140. The second printed circuit board 128 and the third printed circuit board 138 may at least partially be arranged such that the second conducting layer 134 and the third conducting layer 140 are spatially separated by the second isolating layer 136. The third printed circuit board 138 may further comprise a third isolating layer 142. The second printed circuit board 128 and the third printed circuit board 138 may then at least partially be arranged such that the second conducting layer 134 and the third conducting layer 140 are spatially separated by the third isolating layer 142. Further, the second printed circuit board 128 and the third printed circuit board 138 may at least partially be arranged such that the second conducting layer 134 and the third conducting layer 140 are spatially separated by the second isolating layer 136 and the

third isolating layer 142. Again, the second isolating layer 136 may specifically be in direct contact with the third isolating layer 142.

Referring to both FIG. 2 and FIG. 3 where applicable, at least one of the first conducting layer 130, the second conducting layer 134 and the third conducting layer 140 may be a structured layer, such as a layer comprising traces or other structures. In principle, at least one of the first conducting layer 130, the second conducting layer 134 and the third conducting layer 140 may however also be a plane layer. As an example, with respect to the arrangement illustrated in FIG. 3, the first conducting layer 130 and the third conducting layer 140 may be structured layers and the second conducting layer 134 may be a plane layer, such as for improving capacitive coupling when using a connecting printed circuit board. Thus, at least one of the first conducting layer 130, the second conducting layer 134 and the third conducting layer 140 may be configured for carrying out an electronic function. The electronic function may be selected from the group consisting of a sense function, a regulation function, a processing function, a communication function, a supply function. At least one of the first conducting layer 130, the second conducting layer 134 and the third conducting layer 140 may comprise copper. At least one of the first isolating layer 132, the second isolating layer 136 and the third isolating layer 142 may comprise polyimide. Other options for materials or electronic functions may of course also be feasible.

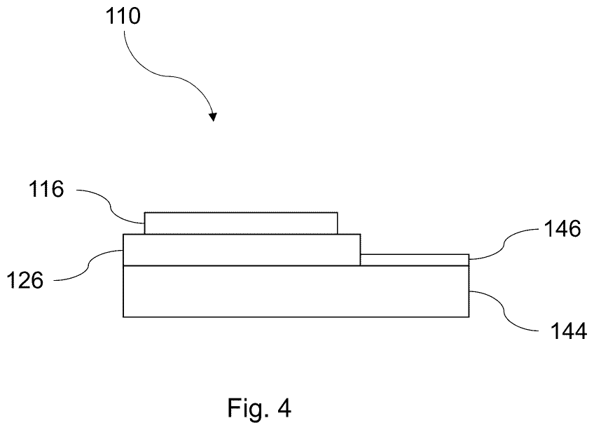

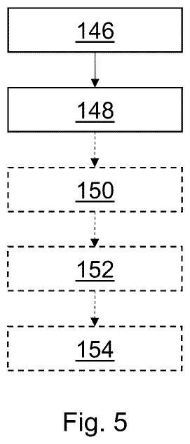

FIG. 4 schematically illustrates an example of a mechanical setup of the battery management system 110. The battery management system 110 may comprise at least one carrier 144. The carrier 144 may be configured for mechanically carrying further components. Specifically, the carrier 144 may be configured for carrying at least one printed circuit board, such as the first printed circuit board 126 described above. Thus, at least one of the above-mentioned printed circuit boards 126, 128 and 138 may be mechanically attached to the carrier. Additionally or alternatively, the carrier 144 may be configured for carrying at least one battery cell connector 146. The battery cell connector 146 may be configured for electronically connecting a plurality of battery cells 112. At least one of the printed circuit boards 126, 128 and 138 may be electronically connected to the battery cell connector 146 and thus indirectly to the battery cells 112. At least one of the printed circuit boards 126, 128 and 138 may carry a cell supervision circuit 116. In other words, a cell supervision circuit 116 may be mounted on for instance the first printed circuit board 126. The cell supervision circuit 116 may be configured for monitoring at least one battery cell 112. Thus, the cell supervision circuit 116 may specifically be indirectly connected to the battery cell 112 for monitoring the battery cell 112.

FIG. 5 illustrates a flow chart of an example of a method for arranging and operating a battery management system 110. The method comprises the following method steps. The presented method steps may be performed in the indicated order. It shall be noted, however, that a different order may also be possible. The method may comprise further method steps which are not listed. Further, one or more of the method steps may be performed once or repeatedly. Further, two or more of the method steps may be performed simultaneously or in a timely overlapping fashion.
a) (denoted by reference numeral 146) arranging the first printed circuit board 126 and the second printed circuit board 128 within the battery management system 110 such that the first printed circuit board 126 and the second printed circuit board 128 are galvanically isolated and electronically coupled via a non-conductive electronic coupling, and
b) (denoted by reference numeral 148) transferring an electronic signal between the first printed circuit board 126 and the second printed circuit board 128 via the non-conductive electronic coupling between the first printed circuit board 126 and the second printed circuit board 128.

The method may further comprise one or more of the following steps:
c) (denoted by reference numeral 150) arranging the third printed circuit board 138 and the second printed circuit 128 such that the second printed circuit board 128 and the third printed circuit board 138 are galvanically isolated and electronically coupled via a non-conductive electronic coupling,
d) (denoted by reference numeral 152) transferring an electronic signal between the second printed circuit board 128 and the third printed circuit board 138 via the non-conductive electronic coupling between the second printed circuit board 128 and the third printed circuit board 138, and
e) (denoted by reference numeral 154) transferring an electronic signal between the first printed circuit board 126 and the third printed circuit 138 board via the second printed circuit board 128.

Thus, the same electronic signal may specifically be transferred from the first printed circuit board 126 via the second printed circuit board 128 to the third printed circuit board 138. For further details regarding the described method, reference may also be made of the description of the battery management system 110 above. As already indicated, the described battery management system 110 and/or the described method may specifically be used in an

automotive application. Thus, the battery management system 110 and/or the method may be used for battery management in a vehicle, such as for managing battery cells 112 in a vehicle. Generally, the terms first, second, third and, if applicable, further numberings are merely used herein as nomenclature, without indicating an order or ranking. The terms first, second, third and, if applicable, further numberings are only used for indicating that different elements of the same kind are referred to.

In addition to the above-described examples, the following examples are disclosed herein:

Example 1: A battery management system comprising a plurality of printed circuit boards, wherein a first printed circuit board and a second printed circuit board are galvanically isolated from each other and arranged for transferring an electronic signal via a non-conductive electronic coupling between each other.

Example 2: The battery management system according to the preceding Example, wherein the non-conductive electronic coupling is a capacitive coupling.

Example 3: The battery management system according to any one of the preceding Examples, wherein the first printed circuit board and the second printed circuit board at least partially overlap with each other.

Example 4: The battery management system according to any one of the preceding Examples, wherein the first printed circuit board comprises a first conducting layer and a first isolating layer, wherein the second printed circuit board comprises a second conducting layer, wherein the first printed circuit board and the second printed circuit board are at least partially arranged such that the first conducting layer and the second conducting layer are spatially separated by the first isolating layer.

Example 5: The battery management system according to the preceding Example, wherein the second printed circuit board further comprises a second isolating layer, wherein the first printed circuit board and the second printed circuit board are at least partially arranged such that the first conducting layer and the second conducting layer are spatially separated by the first isolating layer and the second isolating layer.

Example 6: The battery management system according to the preceding Example, wherein the first isolating layer is in direct contact with the second isolating layer.

Example 7: The battery management system according to any one of the three preceding Examples, wherein at least one of the first conducting layer and the second conducting layer is a structured layer.

Example 8: The battery management system according to any one of the four preceding Examples, wherein at least one of the first conducting layer and the second conducting layer is configured for carrying out an electronic function.

Example 9: The battery management system according to the preceding Example, wherein the electronic function is selected from the group consisting of: a sense function, a regulation function, a processing function, a communication function, a supply function.

Example 10: The battery management system according to any one of the preceding Examples, further comprising a third printed circuit board, wherein the second printed circuit board and the third printed circuit board are galvanically isolated from each other and arranged for transferring electronic signals via a non-conductive electronic coupling between each other

Example 11: The battery management system according to the preceding Example, wherein the first printed circuit board, the second printed circuit board and the third printed circuit board are arranged for transferring an electronic signal between the first printed circuit board and the third printed circuit board via the second printed circuit board.

Example 12: The battery management system according to any one of the two preceding Examples, wherein the electronic coupling between the second printed circuit board and the third printed circuit board is a capacitive coupling.

Example 13: The battery management system according to any one of the three preceding Examples, wherein the second printed circuit board and the third printed circuit board at least partially overlap with each other.

Example 14: The battery management system according to any one of the four preceding Examples, wherein the second printed circuit board comprises a second conducting layer and a second isolating layer, wherein the third printed circuit board comprises a third conducting layer, wherein the second printed circuit board and the third printed circuit board are at least partially arranged such that the second conducting layer and the third conducting layer are spatially separated by the second isolating layer.

Example 15: The battery management system according to the preceding Example, wherein the third printed circuit board further comprises a third isolating layer, wherein the second printed circuit board and the third printed circuit board are at least partially arranged such that the second conducting layer and the third conducting layer are spatially separated by the second isolating layer and the third isolating layer.

Example 16: The battery management system according to the preceding Example, wherein the second isolating layer is in direct contact with the third isolating layer.

Example 17: The battery management system according to any one of the three preceding Examples, wherein at least one of the second conducting layer and the third conducting layer is a structured layer.

Example 18: The battery management system according to any one of the four preceding Examples, wherein at least one of the second conducting layer and the third conducting layer is configured for carrying out an electronic function.

Example 19: The battery management system according to the preceding Example, wherein the electronic function is selected from the group consisting of: a sense function, a regulation function, a processing function, a communication function, a supply function.

Example 20: The battery management system according to any one of the preceding Examples, wherein at least one of the printed circuit boards is a flexible printed circuit board

Example 21: The battery management system according to any one of the sixteen preceding Examples, wherein at least one of the first isolating layer and the second isolating layer and optionally the third isolating layer comprises polyimide.

Example 22: The battery management system according to any one of the eighteen preceding Examples, wherein at least one of the first conducting layer and the second conducting layer and optionally the third conducting layer comprises copper.

Example 23: The battery management system according to any one of the preceding Examples, wherein the battery management system is a distributed battery management system.

Example 24: The battery management system according to any one of the preceding Examples, wherein at least one of the printed circuit boards carries a cell supervision circuit configured for monitoring a battery cell.

Example 25: The battery management system according to any one of the preceding Examples, further comprising at least one battery cell connectors configured for connecting a plurality of battery cells.

Example 26: The battery management system according to the preceding Example, wherein at least one of the printed circuit boards is electronically connected to the battery cell connector.

Example 27: The battery management system according to any one of the two preceding Examples, further comprising at least one carrier configured for carrying at least the battery cell connector.

Example 28: The battery management system according to the preceding Example, wherein at least one of the printed circuit boards is mechanically attached to the carrier.

Example 29: The battery management system according to any one of the five preceding Examples, further comprising a plurality of battery cells.

Example 30: The battery management system according to the preceding Example, wherein the battery cells form a battery stack.

Example 31: The battery management system according to any one of the five preceding Examples, further comprising a host controller configured for controlling the battery management system.

Example 32: a Method Comprising:
a) arranging a first printed circuit board and a second printed circuit board within a battery management system such that the first printed circuit board and the second printed circuit board are galvanically isolated and electronically coupled via a non-conductive electronic coupling, and
b) transferring an electronic signal between the first printed circuit board and the second printed circuit board via the non-conductive electronic coupling between the first printed circuit board and the second printed circuit board.

Example 33: The method according to the preceding Example, wherein the non-conductive electronic coupling between the first printed circuit board and the second printed circuit board is a capacitive coupling.

Example 34: the method according to any one of the preceding method examples, further comprising:
c) arranging a third printed circuit board and the second printed circuit board such that the second printed circuit board and the third printed circuit board are galvanically isolated and electronically coupled via a non-conductive electronic coupling, and
d) transferring an electronic signal between the second printed circuit board and the third printed circuit board via the non-conductive electronic coupling between the second printed circuit board and the third printed circuit board.

Example 35: The method according to the preceding Example, further comprising:
e) transferring an electronic signal between the first printed circuit board and the third printed circuit board via the second printed circuit board.

Example 36: The method according to any one of the two preceding Examples, wherein the non-conductive electronic coupling between the second printed circuit board and the third printed circuit board is a capacitive coupling.

Example 37: The method according to any one of the preceding method Examples, wherein the first printed circuit board, the second printed circuit board and optionally the third printed circuit board are arranged within a battery management system according to any one of the preceding Examples referring to a battery management system.

Example 38: A use for an automotive application of at least one of a battery management system according to any one of the preceding Examples referring to a battery management system and a method according to any one of the preceding method Examples.

Although specific examples have been illustrated and described herein, it will be appreciated by those of ordinary skill in the art that a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosure and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosure, as well as specific examples thereof, are intended to encompass equivalents thereof.

1. A battery management system comprising a plurality of printed circuit boards, wherein a first printed circuit board and a second printed circuit board are galvanically isolated from each other and arranged for transferring an electronic signal via a non-conductive electronic coupling between each other.

2. The battery management system of claim 1, wherein the non-conductive electronic coupling is a capacitive coupling.

3. The battery management system of claim 1, wherein the first printed circuit board and the second printed circuit board at least partially overlap with each other.

4. The battery management system of claim 1, wherein the first printed circuit board comprises a first conducting layer and a first isolating layer, wherein the second printed circuit board comprises a second conducting layer, wherein the first printed circuit board and the second printed circuit board are at least partially arranged such that the first conducting layer and the second conducting layer are spatially separated by the first isolating layer.

5. The battery management system of claim 4, wherein the second printed circuit board further comprises a second isolating layer, wherein the first printed circuit board and the second printed circuit board are at least partially arranged such that the first conducting layer and the second conducting layer are spatially separated by the first isolating layer and the second isolating layer.

6. The battery management system of claim 4, wherein at least one of the first conducting layer and the second conducting layer is a structured layer.

7. The battery management system of claim 4, wherein at least one of the first conducting layer and the second conducting layer is configured for carrying out an electronic function.

8. The battery management system of claim 1, further comprising a third printed circuit board, wherein the second printed circuit board and the third printed circuit board are galvanically isolated from each other and arranged for transferring electronic signals via a non-conductive electronic coupling between each other.

9. The battery management system of claim 8, wherein the first printed circuit board, the second printed circuit board and the third printed circuit board are arranged for transferring an electronic signal between the first printed circuit board and the third printed circuit board via the second printed circuit board.

10. The battery management system of claim 1, wherein at least one of the printed circuit boards is a flexible printed circuit board.

11. The battery management system of claim 1, wherein the battery management system is a distributed battery management system.

12. The battery management system of claim 1, wherein at least one of the printed circuit boards carries a cell supervision circuit configured for monitoring a battery cell.

13. The battery management system of claim 1, further comprising at least one battery cell connector configured for connecting a plurality of battery cells.

14. The battery management system of claim 13, wherein at least one of the printed circuit boards is electronically connected to the battery cell connector.

15. The battery management system of claim 13, further comprising at least one carrier configured for carrying at least the battery cell connector, wherein at least one of the printed circuit boards is mechanically attached to the carrier.

16. A method comprising:
a) arranging a first printed circuit board and a second printed circuit board within a battery management system such that the first printed circuit board and the second printed circuit board are galvanically isolated and electronically coupled via a non-conductive electronic coupling, and
b) transferring an electronic signal between the first printed circuit board and the second printed circuit board via the non-conductive electronic coupling between the first printed circuit board and the second printed circuit board.

17. The method of claim 16, wherein the non-conductive electronic coupling between the first printed circuit board and the second printed circuit board is a capacitive coupling.

18. The method of claim 16, further comprising:
c) arranging a third printed circuit board and the second printed circuit board such that the second printed circuit board and the third printed circuit board are galvanically isolated and electronically coupled via a non-conductive electronic coupling, and
d) transferring an electronic signal between the second printed circuit board and the third printed circuit board via the non-conductive electronic coupling between the second printed circuit board and the third printed circuit board.

19. The method of claim 18, further comprising:
e) transferring an electronic signal between the first printed circuit board and the third printed circuit board via the second printed circuit board.

20. The method of claim 16, wherein the method is used for an automotive application.
